(19) United States
(12) Patent Application Publication
(10) Pub. No.: US 2016/0313603 A1
(43) Pub. Date: Oct. 27, 2016

(54) Unknown

(71) Applicant: SCHOTT AG, Mainz (DE)

(72) Inventors: Marten WALTHER, Alfeld (DE); Dirk APITZ, Lousanne (CH)

(73) Assignee: SCHOTT AG, Mainz (DE)

(21) Appl. No.: 15/041,451

(22) Filed: Feb. 11, 2016

(30) Foreign Application Priority Data
Feb. 11, 2015 (DE) 102015001668.7
Jan. 19, 2016 (EP) 16151898

(51) Int. Cl. G02F 1/1335; C23C 14/22; B05D 1/18; C23C 16/44

(52) U.S. Cl. CPC G02F 1/133555; C23C 16/44; C23C 14/22; B05D 1/18; G02F 1/133502; G02F 2203/05; G02F 2203/09; G02F 2203/11

(57) ABSTRACT

An indicator or display unit device is provided that includes a first panel element, a second panel element, and an IR-reflecting coating and a filler material between the first and second panel elements. The panel elements, the IR-reflecting coating, and the filler material form a composite. An antireflection coating in the visible wavelength region is on an outer side of the first panel element or the outer side of the first and second panel elements. The filler material includes a first laminating film, a second laminating film, and an additional film. The IR-reflecting coating is on the additional film. The device has an IR solar reflectance that lies in the range of 45% to 95% in the wavelength region of 780 nm to 3000 nm and a reflectance Rᵥᵢₛ that is less than or equal to 4% in the visible wavelength region of 400 nm to 780 nm.

### CROSS REFERENCE TO RELATED APPLICATION

This application claims the benefit under 35 U.S.C. §119(a) of German Patent Application No. 102015001668.7 filed Feb. 11, 2015 and claims the benefit of European Patent Application No. 16151898 filed Jan. 19, 2016, the entire contents of both of which are incorporated herein by reference.

### BACKGROUND OF THE INVENTION

1. Field of the Invention

The present invention relates to a device with IR-reflecting coating, in particular for indicator or display units, architectural applications, windshields, having at least one first pane-shaped or panel-shaped element and a second pane-shaped or panel-shaped element, and a coating introduced between the first and the second pane-shaped or panel-shaped elements.

2. Description of Related Art

Particularly in indicator or display units that are preferably employed outdoors, and in which sunlight is directly incident on the display device, there is the problem that display units must be cooled by means of complex cooling systems, in order to prevent an inadmissible heating of same. This is then particularly problematic when the display units outdoors are subjected to intense solar radiation. Indicator units may comprise displays, for example. The entire spectrum with wavelengths in the range of 100 nm up to about 3000 nm are relevant for heating due to solar radiation. In general, the display itself attempts to achieve an active cooling between the front panel and the display. Especially in regions with high solar radiation, the total radiation leads to a very intense heating of the display unit due to incident light. In particular, when solar radiation cannot be adequately avoided, the display can be heated to above its maximum permissible operating temperature. This causes the display to turn black and it is no longer readable.

Intense solar radiation, however, is also problematic for other applications, e.g., in devices that are employed as glazings, for example, in buildings, e.g., in the architectural field. Here, the heating of a building by solar radiation is particularly to be avoided. Another field of application would be to utilize the device as a windshield.

Ideally, the spectrum must be divided selectively into different wavelength regions. With an energy input from sunlight in the UV region of 100 nm to 400 nm, where a transmission of electromagnetic radiation of 0% is ideally required, in the visible spectral region from 380 nm to 780 nm, where transmission of electromagnetic radiation is required to be as high as possible, ideally 100%, and reflection is required to be as low as possible, ideally 0%, and in the infrared (IR) region from 700 nm to 3000 nm, where transmission of the electromagnetic radiation is required to be as small as possible with values approaching of 0%, and reflection is required to be as high as possible, in the ideal case, 100%. In actual application, the UV region hardly contributes to heating, since only small quantities of energy are contained in the solar spectrum. For the visible region from 380 nm to 780 nm, transmissions of >70% and reflectances Rᵥᵢₛ of smaller than 3% should be achieved. In the region of 780 nm to approximately 3000 nm, a high reflectance of more than 40% with simultaneous very low transmission of less than 10% should be achieved; thus an effective protection from the sun will be obtained, with simultaneous increase in the optical contrast of the display device due to low optical reflectance.

Different solutions for reducing the reflection in the IR region have become known; however, they do not meet the desired values.

A laminated glass pane or panel having an IR-reflective layer, in particular for large-surface glazings, has become known from US 2009/0237782 A1.

DE-A-15 96 810 shows a large-surface glazing having a metal laver, particularly a gold or copper layer that reflects infrared radiation and long-wave light.

A laminated glass pane or panel reflecting solar and heat radiation has become known from DE-C-199 27 683.

DE-A-195 03 510 shows a method for producing an IR-reflecting laminated glass pane or panel.

DE-A-196 44 004 shows a laminated glass pane or panel reflecting heat radiation for motor vehicles.

DE-T-694 30 986 shows a light valve having a low-emissivity coating as an electrode.

Indicator or display devices have become known from DE-A-28 24 195 or JP-A-2006-162890.

Proceeding therefrom, DE-A-10 2009 051 116 has become known. It describes a device in the form of a laminated glass having two panel-shaped elements and an IR-reflecting coating introduced between these elements, whereby this coating is usually applied directly onto one of the panel-shaped elements. In addition, this device can have an antireflection layer on one or both outer surfaces and matching layers lying inside in the laminate, complementary to the IR-reflecting coating, for optimizing the optical effect of the device. Here, a disadvantage is the complex production method, in which fixed dimensions must be processed, and thus the surface area utilization is greatly reduced in the low-E sputtering system, and thus only a batch production is possible. Low-E (from the English “low emissivity”) in this case means that a surface has a low emissivity (in the IR), such as, e.g., polished metal surfaces. This property is typically accompanied by a high reflectance (in the IR). In particular, the limitation to fixed dimensions applies in the processing of chemically or thermally hardened glasses, which always must be present inherently in final format. A processing of bent glasses is also not possible. Since the optical properties of the low-E layers must be modified when compared to standard layers, based on the two symmetrical interfaces in the laminate, the process must be run again in a complex manner, so that here only one production campaign is possible. Alternatively, stock dimensions for laminates with the outer AR and an inner IR protection can be coated, of course, but this will drive up costs for logistics and protection, since the IR protection layers rapidly corrode and are soft.

A heat-reflecting glass plate having a multilayer coating has become known from DE-A-39 41 046. The multilayer coating is composed of a film of indium/tin oxide (ITO) or AlN that has been deposited on the glass plate, a heat-reflecting layer made of Ag or Cu that has been deposited on the base layer with a thickness of 4 to 20 nm (40 to 200 Å), a layer of Zn metal on the reflection layer with a thickness of 2 to 20 nm (20 to 200 Å), and an outer protective layer, either made of ITO or AlN. The sequence of reflection layer, blocking layer, and outer protective layer can be applied several times, one covering the other, so that each reflection layer of Ag or Cu will be covered by a blocking layer of Zn, and the latter in turn will be covered by a protective layer of ITO or AlN. An increased resistance to moisture results due to the multilayer coating according to DE-A-39 41 046.

US 2009/0237782 A1 shows a substrate that reflects in the near infrared. The substrate known from US 2009/0237782 A1 onto which the IR-reflecting coating is applied can be a glass plate or a transparent polymer. In addition, US 2009/0237782 A1 shows a laminated glass with two glass panels, wherein two films, for example a PVB film as well as a substrate having an IR-reflecting coating are introduced between the two glass panels. Of course, there is no information in US 2009/0237782 A1 relating to the level of IR solar reflectance or to the reflectance Rᵥᵢₛ in the visible wavelength region.

A laminated glass panel reflecting solar and heat radiation has become known from DE-C-199 27 683. The laminated glass panel according to DE-C-199 27 683 has the solar protection layer on a surface of the outer glass panel lying inside the composite.

### SUMMARY

The object of the invention is thus to provide a device for the most varied applications, a device that avoids the disadvantages of the prior art and makes possible an inexpensive and flexible production with less complexity, but to provide a device with a great protective effect vis-a-vis solar radiation, in particular, for indicator or display units, or architectural applications, or as a windshield.

According to the invention, the device comprises a first panel-shaped element and a second panel-shaped element, wherein an IR-reflecting coating is introduced between the first and the second panel-shaped elements. In addition, a filler material and at least one film are introduced between the first and the second panel-shaped elements. Preferably, the filler material comprises at least two films. These films can be laminating films or support films. Laminating films liquefy under pressure at laminating conditions below 200° C. and bond adhesively. Support films, in contrast, do not have such a property, so that usually a laminate cannot be produced by support films, in the sense of a laminated safety glass. A glass without these safety features can also be utilized for these types of displays, since the heat-optical function is not affected thereby. The at least one film that can support the IR-reflecting coating or the IR-reflecting coatings can be a polymer film, but it can also be a glass substrate. In general, the film can be a film composed of an organic material, such as a polymer film, or an inorganic material, for example, a glass film or a glass-like film composed of a thin glass, such as, for example, the glass AF32 or D263 of SCHOTT AG, Mainz. As an alternative to thin glass, ultrathin glass, such as is offered by SCHOTT AG, Mainz, can also be used, which is not only flexible, but also can be rolled. The disclosure content of the official website of SCHOTT AG, www.schott.com/advancedoptics/german/products/wafers-and thin glass/index.htm, which shows and describes these glasses, is incorporated to the full extent in the present Application. The flexibility of polymer films or glass films is not a compelling property for the described application case. Even glasses of 2-mm thickness have a sufficient flexibility for the described application case. The first and the second panel-shaped elements, the IR-reflecting coating and the filler material form a composite. The space between the panels is filled with the filler material in the form of films. The filler material is thus not gaseous as in the case of insulating glass composites. In addition, an antireflection coating, in particular in the visible wavelength region, is applied onto the outer side of the first panel-shaped element and of the second panel-shaped element. As described above, the IR-reflecting coating is applied onto the additional films or at least onto a partial region of the additional films. In the wavelength region of 780 nm to 2500 nm, the IR solar reflectance of the device lies in the range of 30% to 95%, preferably in the range of 50% to 80%, and in the visible wavelength region of 400 nm to 780 nm, the reflectance Rᵥᵢₛ lies in the range of less than or equal to 4%, preferably less than or equal to 3%, and simultaneously, due to absorption in the low-E layers, the energy transmission for sunlight, averaged in the region of 380 nm to 3000 nm, lies below 45%, preferably below 40%.

In contrast to the embodiments that are described in DE-B-10 2009 051 116.4 or WO 2011/050908, the embodiment according to the invention has the advantage that the films having an IR-reflecting coating can be very easily produced. The introduction between two films, in particular laminating films, e.g., two PVB films, on the one hand, has the advantage of a secure inclusion of the applied IR-reflecting coating, which preferably comprises silver layers, and thus tends toward oxidation; on the other hand, the films, in particular the laminating films themselves, can be selected such that abrupt jumps in the refractive index do not occur in the transitions from the glass to the laminating film and then to the film having at least one applied IR-reflecting coating. It is particularly preferred if the film having the IR-reflecting coating is introduced in the form of a sandwich between two laminating films. The film onto which the IR-reflecting film is applied preferably has a thickness that lies between 10 μm and 5 mm. The laminating films provide a protection against corrosion according to the invention.

The structure according to the invention has advantages for the manufacture of devices with IR-reflecting coating. One advantage is that the antireflecting glasses need not be introduced into the production unit for the IR coating, since the IR layer is applied separately onto a film-like substrate, and the laminate is only assembled later. In exemplary production units for the IR coating, for example in sputtering units, the glass is transported by the bottom side, the bottom side already comprising the antireflecting layer. A roll transport in the production unit for an already coated glass, however, harbors the increased risk of scratching the antireflecting layer, since the units are often not specially designed for these sensitive layers.

The possible separation of processes in the layer construction according to the invention has the further advantage that the glass panel coated with an antireflecting coating, as well as the films coated with an IR-reflecting coating can be provided and stored separately in formats optimized for the technology of the production unit. Since the preliminary products are produced separately and only the laminating step must have the customer-specific format in the assembly of the preliminary products to form the final product, manufacture and storage are greatly simplified.

In fact, WO-A-2011/050908 shows an IR-reflecting coating that is applied onto a film, but not the sandwich structure according to the invention, which makes possible a separate manufacture of individual preliminary products.

A composite according to the invention makes it possible for IR-reflecting coatings, for example, based on multilayer systems that contain metal layers, particularly silver layers—so-called low-E coatings—to be utilized; these possess a very high reflectance in the range of IR radiation from 780 nm to 2000 nm, preferably a reflectance of >50% in the wavelength region from 900 nm to 1400 nm. The IR-reflecting layers utilized have increasingly more reflectance starting from 700 nm; i.e., a reflection also takes place in the far infrared. Preferably, the IR-reflecting layers comprise a metal, in particular silver. Such layers have a broadband reflectance in the infrared, which extends into the infrared far above 1400 nm. These are filters with high reflectance, predominantly in the region of the near infrared.

Understood as transparent elements or layers are, in particular, layers or glasses with a transmission of greater than or equal to 50 per cent, preferably >70%, in the visible wavelength region from 380 nm to 780 nm, preferably from 400 nm to 780 nm, in particular from 420 nm to 740 nm.

Due to the fact that the IR-reflecting coating is introduced between the laminating films, it is possible to utilize silver single-layer or multilayer systems, which are highly efficient, but are sensitive to corrosion and/or are not resistant to scratching, as IR-reflecting coatings, and to protect against a chemical or mechanical attack, especially oxidation. For this purpose, e.g., only a zone of less than 5 mm at the edge, in which an IR protective coating is absent, can be present on the periphery, and the latter is hermetically sealed in the manufacture of the composite. The IR-reflecting coating can be protected from corrosion by an edge or an edge ablation and/or a cutting back, which is particularly important in the case of IR-reflecting layers that comprise silver. By means of an edge or an edge ablation and/or a cutting back, it is avoided that the laminated film having the IR-reflecting coating, in particular, the metal layers, preferably the silver layers, lay open laterally and thus can be attacked. According to the present invention, the first and the second laminating films, between which the film having the IR-reflecting coating is disposed, are used as corrosion protection for the IR coating. In contrast, the laminates known from DE-A-10 2009 051 116 and US 2009/0237 782 A1 do not serve as corrosion protection, in particular for an IR-reflecting coating, but rather are provided for the purpose of mechanical stability for the composite.

Alternatively or additionally, the outer region of the composite where the films are in contact with air, can be provided with a hermetic seal, e.g., by means of butyl rubber, as in insulation glazings of the window industry, or by means of a metal composite that prevents diffusion. This solution, however, usually leads to an esthetically unsatisfactory appearance of the glazing, so that an uncoated edge zone is the predominant solution.

Such highly reflective IR coatings based on silver layers are designated as so-called “soft coatings” and are described, for example, in very great detail, in “Hans-Joachim Glaser, Dünnfilmtechnologie auf Flachglas [Thin Film Technology on Flat Glass], pp. 167-171”. The disclosure content of this document is incorporated to the full extent in the present Application. In order to minimize the corrosion sensitivity of the coating introduced between the first panel-shaped element and the second panel-shaped element, it is advantageously provided that the edge of the first panel-shaped element and/or of the second panel-shaped element does (do) not have an IR-reflecting coating. It is particularly preferred if the IR-reflecting coating has a very high reflectance in the wavelength region of 780 nm to 3000 nm. In the ideal case, the reflectance would be 100% for wavelengths in the region from 780 nm to 3000 nm.

If the radiation emitted by the sun, thus the spectrum of sunlight, is approximated by means of a Planck radiator with a temperature T_{radiator}=5762 K, then it can be derived that, by disregarding the UV component having wavelengths of <380 nm, approximately 55% of the energy or the intensity of sunlight lies in the visible wavelength region from 380 nm to 780 nm, and approximately 45% of the energy lies in the IR wavelength region from 780 nm to 3000 nm. For an ideal IR mirror with a reflectance of 100% in the wavelength region from 780 nm to 3000 nm, therefore, 45% of the sunlight, i.e., the IR component, would be reflected.

In order to indicate the quality of the reflectance of the coating for IR radiation, the IR solar reflectance will be defined in the present Application. The spectral reflectance of the IR coating in the wavelength region from 780 nm to 3000 nm, combined with the relative intensity of the approximated spectrum of sunlight for a Planck radiator with a temperature of 5762 K is defined as IR solar reflectance in this Application. Whereas the IR solar reflectance for solutions having films according to the prior art is approximately 40%, systems having an IR coating according to the invention are characterized by an IR solar reflectance in the range of 45% to 95%, preferably from 50% to 90%, and by a reflectance Rᵥᵢₛ in the visible wavelength region of 380 nm to 780 nm in the range of less than or equal to 4%, preferably less than or equal to 3%.

The laminating film and/or the film that supports the IR-reflecting coating and that is introduced between the two panels preferably comprise(s) polymer materials. The polymer film has a transparency of greater than 70%, preferably greater than or equal to 85%, more preferably greater than or equal to 88%, most preferably greater than or equal to 92%. For example, a polymer film made of PMMA in the indicated thickness range has a transparency of greater than/equal to 92%; correspondingly, a polymer film made of PET has a transparency of greater than or equal to 88%; and correspondingly, a polymer film of PC has a transparency of greater than or equal to 85%. For other applications, except for an application in a display unit, above all in the fields of architecture and furniture, this film, however, may also be colored, translucent, or opaque, or may be a support for a picture or a document.

The invention also comprises IR coatings that are applied onto a glass substrate instead of a polymer film, the substrate then in turn being formed by polymer films having the antireflecting layers as a composite with three glass panels. In this case, the flexibility of the films having the IR coating is lost. In the sense of optical properties, however, a product analogous to the film is formed, which is comprised to the full extent by the disclosure content of the present Application.

Polymer films on which the IR-reflecting coating is (are) applied preferably have, but not exclusively, a thickness from less than or equal to 400 μm, preferably less than or equal to 200 μm, more preferably from less than or equal to 50 μm to 20 μm. If PET films are utilized as support films for the IR coating, then the thickness lies between 25 and 90 μm, preferably 60 μm. The polymer film as support for the IR-reflecting coating is preferably composed of a polyethylene terephthalate (PET), a polycarbonate (PC), a polymethyl methacrylate (PMMA), a polyamide (PA), a polyimide (PI), or a polyolefin such as polyethylene (PE) or polypropylene, or in each case, one of their blends, copolymers, or derivatives of, or a fluorinated and/or chlorinated polymer, such as, for example, ethylene-tetrafluorethylene (ETFE), polytetrafluorethylene (PTFE), polyvinyl chloride (PVC), polyvinylidene chloride (PVdC) or polyvinylidene fluoride (PVDF). The IR coating is applied onto this polymer film.

The laminating film is also a polymer film, in particular, made of polyvinyl butyral (PVB) or ethylene vinyl acetate (EVA) or polyamide (PA) or polymethyl methacrylate (PMMA) or polyurethane (PUR). Preferably, the laminating film possesses a UV protective effect that effectively absorbs radiation below 380 nm. In particular embodiments, doped films are known, in which a protective effect is also achieved up to 420 nm. The laminating films usually have a thickness of 380 μm or 760 μm. The necessary thickness of the laminating films can be varied and can be matached to the static requirements of the composite that forms. Usually, several films are separately placed on top of one other for this and joined together in one step.

The films named above may also comprise, in addition to the coating reflecting IR radiation according to the invention, other coatings, for example, low-E layers, such as a coating made of tin oxide doped with fluorine, applied onto the film. Such a low-E layer, however, can also be applied alternatively on an inner-lying surface of the first and/or the second panel-shaped element in the composite. Such coatings are known and are applied, for example, by means of spray pyrolysis, whereby a powder-form tin and fluorine compound, suspended in a gaseous carrier flow, is applied onto the glass surface, which has a temperature in the range of 400° C. to 650° C., and reacts there via pyrolysis to form the desired active layer.

For manufacturing the composite, for example, by means of a polymer material, a PVB, EVA, PA, PMMA or PUR film, the polymer material or the film is liquefied or softened by means of elevated temperature under pressure and bonded to the first panel-shaped element and to the second panel-shaped element, producing the composite. Here, it is preferred that the IR-reflecting coating is bonded directly.

The IR-reflecting coating may be composed of at least two silver function layers, preferably of different thickness, each of which is enclosed by dielectric layers. The IR-reflecting coating is applied onto a transparent polymer film according to the invention. In the composite, the IR-reflecting coating is inlaid between the thermoplastic laminating films or is enclosed by the latter. In one embodiment, a preliminary composite made of two or more films can also be manufactured.

IR-reflecting coatings, for example, are also low-E coatings. The low-E coating can be composed of one or more metal layers that are highly conductive, for example, based on transparent metal layers, particularly silver layers, which have a very high reflectance in the region of near IR radiation in the wavelength region from 780 nm to 3000 nm. In addition to a low-E coating based on silver layers, such as described, for example, in Hans-Joachim Glaser, “Dünnfilmtechnologie auf Flachglas [Thin Film Technology on Flat Glass]”, Karl Hoffmann Publishers, 1999, pp. 155-200 or 219-228, other layers with very good conductivity may also be employed. Examples therefor include gold or aluminum layers. The layers may also be combined with one another in each case.

In addition, however, the IR-reflecting coating can also be composed of a metal oxide or a combination of layers of different metal oxides. Examples of such layers are indium tin oxide (ITO) or a doped tin oxide such as FTO (SnOx:F) or ATO (SnOx:Sb) or a doped zinc oxide such as ZnOx:Ga, ZnOx:F, ZnOx:B or ZnOx:Al. The application of such a layer or layers onto the filler material or, optionally, onto the inner surface of a panel-shaped element in the composite is preferably conducted by means of chemical vapor deposition (CVD) or physical vapor deposition (PVD), dip coating, chemical or electrochemical coating. Here, spray pyrolysis, sputtering, or the sol-gel method are named only by way of example. Application by means of spray pyrolysis is particularly cost-effective, wherein SnOx:F is preferably employed as the coating material. If one wishes to obtain particularly good optical properties, then the preferred application method is sputtering. The sputtering method has been especially established as the standard, since it makes possible metal layers with very high surface conductivity. A high surface conductivity in turn correlates with a good reflection in the near infrared, especially above 780 nm. In addition, a band edge results, without the visible component being too greatly limited. Semiconducting metal oxide layers also have the behavior desired here of high IR reflection with simultaneous good transmission in the visible region.

In one embodiment of the invention, the device comprises a combination of a first and a second IR-reflecting coating. The first IR-reflecting coating contains at least one or two metal layers, preferably silver layers, and is applied onto a film, in particular, a polymer film and has a steep reflectance edge in the near IR. The second IR-reflecting coating is applied on or under the first IR-reflecting coating onto the film or onto another film, or onto the inner-lying surface of the first and/or second panel-shaped element(s) in the composite, and reflects in the intermediate IR region. In this embodiment, both IR-reflecting coatings together form the IR-reflecting coating in the sense of the invention. A combination of a first and a second IR-reflecting coating forms an enhanced IR-reflecting coating in the sense of the invention.

It is particularly preferred with respect to corrosion resistance if the edge of the first panel-shaped element and of the second panel-shaped element do not have an IR-reflecting coating, or the IR-reflecting coating is discontinued at the edge, and secondly, the edge comprises a sealing material. Thus, the coating is insulated from the ambient atmosphere by the laminating itself and, in the simplest case, the sealing material is the laminating film. Alternatively, the insulation or sealing can be applied after the laminating, from outside onto the edge of the composite. In cases with increased corrosion resistance, for example, butyl rubber, which is characterized by low gas permeability, can be used as a possible sealing material. An alternative sealing possibility is sealing by means of a peripheral aluminum foil, which in turn is adhesively bonded to a plastic having low gas permeability.

The edge of the first and/or second panel-shaped element should be configured such that the applied low-E layers do not corrode from the side of the composite. As an effective means, for example, the edge end of the layers can be used, where the low-E layer does not run up to the edge, and thus the laminate can be sealed at the edge directly between upper and lower glass.

Preferably, at least 5 mm of the panel are formed as an edge, where the IR-reflecting coating is discontinued or there is no IR-reflecting coating. The maximum limit of the edge is selected so that the visible region is not disturbed for the observer of the laminated glass panel. In order to increase the contrast and thus the quality of the display, in particular with the use of the glass in the display field, i.e., for display units, it is provided that a non-reflecting or antireflection coating is applied on the outer side of the first panel-shaped element or the outer side of the first and the second panel-shaped elements.

By coating at least one surface of the composite with a non-reflecting coating or antireflection coating, the reflection in the visible wavelength region from 350 nm to 780 nm, particularly 400 nm to 780 nm, more preferably 420 nm to 720 nm, of a device is particularly clearly reduced, and thus the contrast of display devices is clearly increased when compared to devices without an antireflection coating. This contrast refers to the ratio of the light emitted by an indicator or, for example, a display, referred to the radiation of the ambient light reflected by the front panel in front of a region shown as black by the display. The reflectance Rᵥᵢₛ is preferably reduced by 50% to 99% by the antireflection coating when compared with a panel-shaped element not provided with an antireflection coating. If the reflectance Rᵥᵢₛ of the panel-shaped element without an antireflection coating amounts to 8%, for example, then the reflectance Rᵥᵢₛ can be reduced to 0.1% to 6%, preferably to 0.1% to 4% by the antireflection coating. The above-named reflectance Rᵥᵢₛ involves reflectance with standard light D65 (artificial daylight), combined with the sensitivity of the eye. Although the reflection for individual wavelengths may be greater than 2%, for example, a value for Rᵥᵢₛ of 1% or less can result for standard light D65.

By reducing the reflection at the surface of the composite caused by the antireflection coating or non-reflecting coating, as well as within the composite by the low-E layer and, optionally, matching layers, the contrast is clearly increased when compared with an element not provided with an antireflection coating. Interference layer systems are preferably employed as antireflection coatings. In these systems, light is reflected at the interfaces of the antireflection coating. In fact, the waves reflected at the interfaces can be completely extinguished by interference, if phase and amplitude conditions are met.

Such antireflection coatings are realized, for example, in the products AMIRAN, CONTURAN, or MIROGARD of Schott AG. With regard to an interference layer system for broadband antireflection, reference is also made to EP-A-1248959, the disclosure content of which is incorporated to the full extent in the present Application.

In addition to the reduction of the reflection Rᵥᵢₛ in the optically visible spectral region of 380 nm to 780 nm, an increase in the transmission preferably by up to 10% can also be achieved by the antireflection coating.

The non-reflecting or antireflection coating is preferably provided on a side of the first and/or the second panel-shaped element(s) that is outwardly directed, i.e., directed to the air. An application of an antireflection layer on the outwardly directed side, i.e., the side directed to the air, of the first and/or second panel-shaped element has not become known from US 2009/0237782 A1.

Layers that are produced according to different methods are taken into consideration as non-reflecting or antireflection coatings. Such layers can be produced, e.g., according to a sol-gel method, according to a sputtering method, according to an etching method, or in a CVD method. Taken individually, the antireflection coating can be applied with one of the following application methods:

a) The antireflection coating is applied by means of a liquid technique, wherein the layer applied by means of liquid technology is provided by means of one of the following techniques:
the antireflection coating is applied by means of the sol-gel technique;
the antireflection coating is produced from the sol-gel technique as a single interference coating;
the antireflection coating is produced from the sol-gel technique as a multiple interference coating;
the antireflection coating is produced from the sol-gel technique as a triple interference coating, wherein the first layer has a refractive index between 1.6 and 1.8; the second layer has a refractive index between 1.9 and 2.5; and the refractive index of the third layer lies between 1.4 and 1.55.

b) the antireflection coating is produced by means of a high-vacuum technique, wherein the layer applied by means of high-vacuum technology is provided by one of the following techniques;
the antireflection coating is produced as a multiple interference layer system by means of a high-vacuum technique;
the antireflection coating is produced as a single layer system by means of a high-vacuum technique;
the antireflection coating is produced under high vacuum from a sputtering process;
the antireflection coating is produced under high vacuum from a deposition process;

c) the antireflection coating is produced by means of a CVD method, wherein the layer applied by means of a CVD method is provided by one of the following techniques:
the antireflection coating is produced from an online CVD process;
the antireflection coating is produced from an offline CVD process;

d) the antireflection coating is produced by means of an etching method, wherein the layer applied by means of an etching method is provided by one of the following techniques:
the antireflection coating is produced as a porous layer by means of an etching method;
the antireflection coating is produced as a light-scattering surface by means of an etching method.

In order to obtain a high IR reflection and, in particular, an IR solar reflectance in the range from 45% to 95%, preferably from 50% to 90%, for the total system made of the two panel-shaped elements and the solid and liquid filler materials introduced between these elements, the low-E coating system, based on at least one silver layer for achieving high IR reflection, is adjusted. For this purpose, the layers that surround the silver are adjusted so that the antireflection effect is matched to the refractive index of the solid or liquid filler material, in particular the laminating film, e.g., the PVB film. For example, such a matching of refractive index can be achieved with cathode sputtering. For example, cathode sputtering involves a plurality of oxide materials, by means of which such a matching can be carried out. As a basis for the low-E coatings, for example, solar protection layers, Sunbelt Platin, which are produced by the company ARCON (Bucha, Feuchtwangen), can be used, which are modified according to the rules indicated above, i.e., matched to the refractive index of the solid or liquid filler material, in particular, the refractive index of the films. Particularly preferred are methods in which the low-E coating is already applied onto the film in the sputtering process, in particular, the polymer film of the later composite. The Southwall company can be named as a supplier of such layers.

It is possible, in particular, by introducing optical matching layers, which preferably comprise oxide and/or conductive oxide layers, that the reflectance Rᵥᵢₛ of the device is less than or equal to 4%, particularly less than or equal to 3%. The matching layers must operate optically with the layer packet of a metal low-E coating, so that they are preferably applied as a common layer package. In separating the application, however, both layer packages must lie directly above one another.

In another embodiment of the invention, the device comprises at least one, preferably two structured, electrically conductive, transparent layers of a TCO coating. This conductive layer is transparent or practically transparent in the visible wavelength region and can be structured in any way. The structuring is designed according to the use requirements, for example as a sensor or as a sensor and driver for a touch screen. The TCO coating is preferably composed of a metal oxide, particularly indium tin oxide (ITO) or of a doped tin oxide such as FTO (SnOx:F) or ATO (SnOx:Sb). Doped zinc oxides, such as ZnOx:Ga, ZnOx:F, ZnOx:B or ZnOx:Al are also conceivable, however. The application of this layer is preferably conducted by means of chemical vapor deposition (CVD) or physical vapor deposition (PVD), dip coating, chemical or electrochemical coating. Here, spray pyrolysis, sputtering, or the sol-gel method are named only by way of example. Application by means of spray pyrolysis is particularly cost-effective, wherein SnOx:F is preferably employed as the coating material. If one wishes to obtain particularly good optical properties, then the preferred application method is sputtering. However, a coating made of a metal such as silver, gold, or aluminum can also be employed.

Such a TCO coating, in particular an ITO coating, on the one hand, acts as a conductive electrical track, for example, for a sensor, e.g., for a capacitive touch screen. On the other hand, however, it acts as an IR-reflecting coating, particularly in the region of the intermediate IR of wavelengths 2000 nm to 10,000 nm, in the sense of the invention. An above-described IR-reflecting coating, containing at least two silver layers, above all reflects in the region of the near infrared of wavelengths from 780 nm to 3000 nm. A combination of both coatings forms an enhanced IR-reflecting coating in the sense of the invention.

In one embodiment, the TCO coating is applied onto the inner surface of the first panel-shaped element, i.e., the element facing the observer, in the composite. With the use of the coating as a sensor, the coating is composed of two layers, which are separated from one another by a transparent electrical insulation.

Based on the structuring of a TCO layer, coated and uncoated regions of the substrate on which the TCO layer was applied are in contact with the next medium, i.e., the two media enclosing the TCO layers come into contact in regions in which the structure does not have a TCO layer. The structuring would be particularly visible on the outer side, i.e., the side facing air, of the first panel-shaped element, due to the antireflection layer. According to the invention, however, this is prevented by the matching layer. A matching layer is applied on the TCO layer in the direction of the IR-reflecting coating on the film, so that the two possible layer sequences (1) film—IR protective layer—matching layer—TCO—next medium (e.g., glass) and (2) film—IR protective layer—matching layer—next medium (e.g., glass) have the same visual properties and thus the structures for the TCO coating are not visible to the human eye.

In a preferred embodiment of the invention, this matching layer is integrated into the layer structure of the IR-reflecting coating on the film, so that the TCO structure is not visible.

In another embodiment, the TCO coating, or two TCO layers that are electrically insulated from one another, is (are) applied onto the IR-reflecting coating on the film, whereby matching layers are integrated into the layer structure of the IR-reflecting coating on the film, so that the TCO structure is not visible. For application as a touch sensor, the structured TCO layer must lie in the direction of the glass surface to be contacted opposite the low-E layer.

Alternative concepts such as infrared or acoustic surface waveguides for providing the touch display are not integrated with the conductive metal layers and thus can be inserted in a flexible way into the total system.

As a use for the invention, which is particularly characterized in that, on the one hand, it has a high IR solar reflectance, and, on the other hand, a low reflectance in the visual wavelength region, use in the field of indicator or display units, in particular, display units for outdoor use is considered, and here, preferably, liquid display units. The device can be provided as a component of a display unit, such as a display, or it may preferably be applied as a front panel on a display unit. In any case, the edge region of the device is sealed.

With use of an antireflection coating, disruptive reflections that reduce the intrinsically high contrast of LCD displays can be avoided. The contrast is normally defined as the quotient between the maximum and minimum light density or brightness. With a black script on a white background, the brightness of the white background would be divided by the brightness of the black script. In the case of a display with a front panel, the maximum brightness of a white point is set on the display and is additionally superimposed by the ambient light reflected at the surface. The minimum brightness is set analogously by a black point of the display and is superimposed with reflected light. Thus, the contrast of a display is dependent on the surrounding light conditions. Alternatively, it is preferred to define a contrast effect that is independent of the environment and the display—the so-called dynamic contrast, which no longer includes the ambient properties.

For example, the dynamic contrast for an LED television amounts to 2,000,000:1.

The influence of very good antireflective front panels according to the invention shall be explained on the following examples. In the first case, the effect is observed for an LED outdoor image screen with a brightness of 5000 cd/m² with an average overcast sky having a brightness of 2000 cd/m².

There then results a value of 3 *4% (display surface and free-standing front panel) each of which are not antireflected: (5000+2000*0.12)/(2000*0.12)=20, characteristic for good readability, and with the use of an antireflective front panel according to the invention 1*0.3% optically bonded and very good antireflective front panel: (5000+2000*0.003)/(2000*0.003)=800, characteristic for high contrast.

If one observes a light TFT image screen with 1200 cd/m² (contrast 700:1) with a clear sky having a brightness of 8000 cd/m², then there results a value of 3*4% (display-surface and free-standing front panel) not antireflected: (1200+8000*0.12)/(8000*0.12+1200/700)=2, which practically means it is not readable, and with the use of a front panel according to the invention 1* 0.3% optically bonded and very good antireflective front panel: :(1200+8000*0.003)/ (8000*0.003+1200/700)=50, which makes readability possible.

This means that a good front panel with an Rᵥᵢₛ of approximately 0.3% for a reflective side, in the case of a good TFT in sunshine, makes the difference between a practically non-readable and a well readable image screen. For an LED outdoor display, there is a difference between a readable and a brilliant contrast-rich image.

In a specially designed version for further contrast enhancement, the front panel can be joined directly to the display, e.g., by bonding the front panel directly onto the display device or display. In the case of a front panel bonded directly onto the display device, the antireflection layer is omitted on the back, but, depending on the type of structure, there is also the possibility of cooling the display by the air intermediate space. This case, which is also designated as optical bonding, places increased requirements on reflection in the infrared, since only reflection reduces the energy of the irradiating sun, whereas an absorption in the glass and the layers is transported further due to heat transport of the display. In the case of such a structure, the described high IR reflectance gains more significance.

In one embodiment, the device can be used as a touch screen or as a component of a touch screen. In addition to use of the device as a touch screen, the invention also provides a touch screen, the device being designed as a capacitive and/or optical and/or inductive and/or acoustic touch screen.

In this case, the device also comprises, in addition to the IR-reflecting coating, the component for forming the functionality of a touch screen, which in turn can also be a component of the IR-reflecting coating. For example, for a projected-capacitive touch screen (PCT, “projected capacitive touch”), structured electrically conductive layers are provided for the formation of a sensor and driver in the device. One conductive layer serves here as a sensor, while the other one serves as a driver, whereby both layers are insulated from one another. Both layers are simultaneously a component of the IR-reflecting coating. A transparent conductive layer, for example, made of a doped metal oxide, can also be integrated into the device for the formation of a surface-capacitive touch screen. The layer is directly applied and laminated on the inner surface of the first panel-shaped element in the composite, this element facing the observer, or onto a filler material, such as a polymer film. This layer is simultaneously a component of the IR-reflecting coating. If the electrically conductive metal or metal oxide layers just have thin discontinuities due to the electrode structuring, a major part of the surface essentially remains with a high IR protective effect, when compared with the non-conductive layers, and nevertheless, the touch function can be electrically analyzed on the structured regions.

Preferably, the matching layers here are optically matched such that the conductive path structure of the touch screen also is not visible, or is almost not visible, and that, in addition, the reflectance Rᵥᵢₛ of the device is less than or equal to 4%, in particular, less than or equal to 3%.

In addition to the device, in particular the panel for a display unit, the invention also provides a display unit having a display or a display unit and a front panel, wherein the front panel is designed as a device according to the invention, comprising two panel-shaped elements having an IR-reflecting coating lying therebetween, and an antireflection coating on the outer side of the first panel-shaped element or the outer side of the first and the second panel-shaped elements. Liquid crystal display units, e.g., TFT-LCD display units, but also OLED, LED, and plasma display units are also considered as indicator or display units. More preferably, an application in outdoor display devices in direct sunlight is included.

In addition to use in display units, a use as a picture glazing, or in the field of architecture, in particular as a curtain wall, or in automobile glazing is also possible. With use as a curtain wall, the device can prevent heat from penetrating into a building shell. Thus, the invention can effectively keep solar heat out of a building. The device or panel according to the invention also finds use as a windshield, primarily as a windshield that is antireflective, at least on one side. Such a device thus always has at least one antireflective layer.

### BRIEF DESCRIPTION OF THE DRAWINGS

The invention will be explained in further detail below based on the appended drawings, which shall not limit the invention. Taken individually:

FIGS. 1a-b show the structure, in principle, of a device with IR-reflecting coating according to the invention;

FIG. 1a shows a top view onto a device 1 according to the invention, and FIG. 1b shows a section along line A-A;

FIG. 2 shows a liquid crystal display unit having a device according to the invention according to FIGS. 1a-1b;

FIGS. 3a -b show the reflection and transmission curves of the device having an IR coating according to the invention according to FIGS. 1a-1b as a function of the wavelength; and

FIGS. 4a-b show the structure in principle of a device having an IR-reflecting coating according to the invention in the embodiment as a projected-capacitive touch screen.

### DETAILED DESCRIPTION

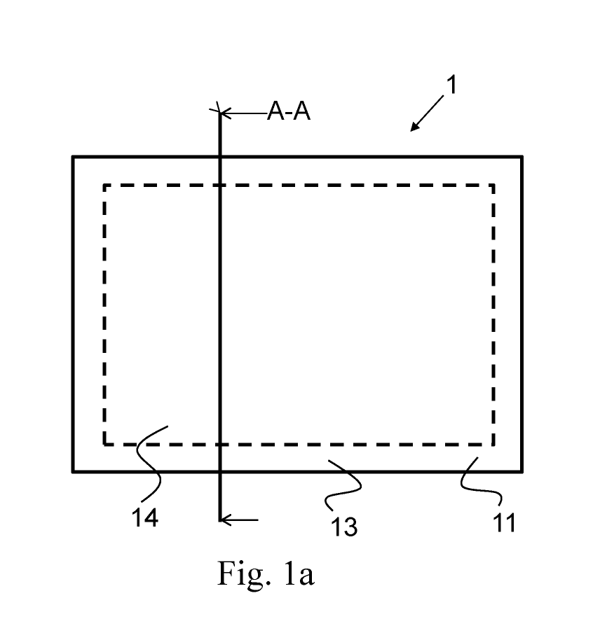

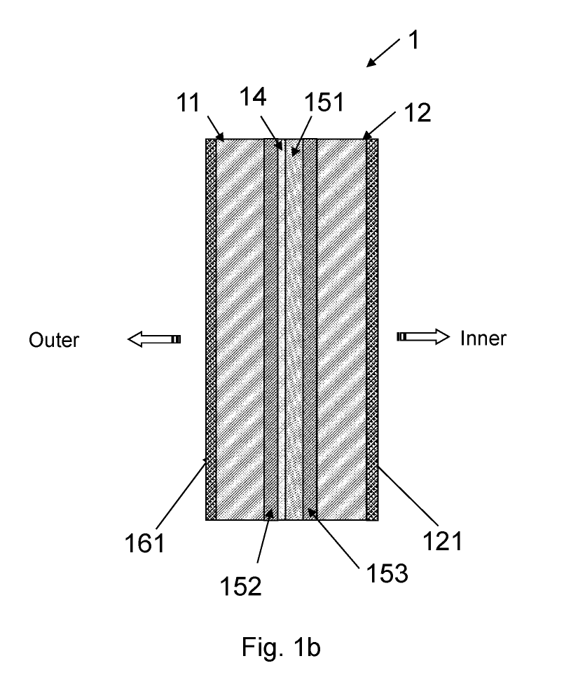

The top view according to FIG. 1a shows the first panel-shaped element 11. The first panel-shaped element 11 comprises an edge 13 that is not provided with an IR-reflecting coating 14. The structure of the system or of device 1, which is also designated a laminated glass element, which is made of two panel-shaped elements 11, 12, can be clearly derived from the sectional view along line A-A according to FIG. 1b. In turn, reference 11 designates the first panel-shaped element. The IR-reflecting coating 14 is applied onto a film 151, which can be a polymer film or a glass substrate, and introduced between the first panel-shaped element 11 and the second panel-shaped element 12. The IR-reflecting coating 14 used here, which is applied onto the film 151, is supplied, for example, under the tradename XIR film of the firm Southwall, Palo Alto, Calif., USA. For example, such an IR-reflecting coating can be composed of a layer structure of more than 15 individual layers, which are applied onto a PET film 60 μm thick. The IR-reflecting coating forms a composite or a composite panel together with the two panel-shaped elements. In order to form the composite, at least two laminating films, in particular, polymer films such as PVB films, are introduced into the intermediate space between the two panes 11 and 12. Both laminating films 152 and 153 solidly join the film 151 and the IR-reflecting layer 14 applied thereon to the first panel-shaped element 11 on the side facing outside (OUTER) of device 1, and to the second panel-shaped element 12 on the side facing inside (INNER) of device 1. In contrast to an insulating laminated glass in which two layers are disposed separate from one another by means of an intermediate space containing a gaseous medium, in the device according to the invention, the panel-shaped elements 11, 12 lie directly on each other, with the filler material in between composed of the two laminating films 152, 153, the film 151 taking up the IR-reflection coating 14, resulting in a laminated glass element. The filler material is characterized in that it has an optical refractive index in the visible region that is matched to the panel-shaped elements 11 and 12, in order to minimize disruptive optical reflections in the inner region of the total composite. The optical refractive index of the filler material (measured at 550 nm) should differ no more than ±0.2, preferably ±0.1 from the refractive index of the elements 11 and 12. As can be seen from the sectional view according to FIG. 1b, the edges 13 of both the first panel-shaped element 11 as well as the second panel-shaped element 12 are not provided with a filler material or an IR-reflecting coating 14. A sealing compound 17 was introduced into the edge region; this prevents moisture from penetrating into the intermediate space between the first panel-shaped element and the second panel-shaped element due to diffusion along the filler material, for example of a film, and thus, the IR-reflecting coating 14 lying between the first and the second panel-shaped elements is protected from corrosion. The IR-reflecting coating 14 preferably contains two silver layers and is applied onto the film 151, in particular the polymer film. Also given are the transmission in the visible spectral region Tᵥᵢₛ, the transmission in the infrared spectral region T(IR), the reflectance Rᵥᵢₛ, and the IR solar reflectance of sunlight incident on the outer side (OUTER). In order to obtain a high transmission Tᵥᵢₛ, preferably Tᵥᵢₛ of greater than 50% and a low reflectance Rᵥᵢₛ, preferably Rᵥᵢₛ of less than or equal to 4%, in particular of less than or equal to 3% in the visible wavelength region, oxide and/or conductive oxide matching layers can be provided. These matching layers can lie over and/or under the metal layers and also can be applied between them, so that they minimize the reflectance Rᵥᵢₛ inside the device 1 or the laminated glass element. Within the framework of the resolution of the drawing, these layers, the thickness of which preferably ranges between 10 nm and 500 nm, cannot be shown as different from the IR-reflecting coating 14. The system of optical matching layers and IR-reflecting layers forms an optically effective total system, which is constructed overall so as to fulfill the previously set forth requirements, for example, with respect to transmission and reflectance.

These layers are combined with diffusion blocking layers for protection of the silver of the IR-reflecting coating 14 as well as matching layers of other materials, e.g., oxides or nitrides, whose refractive index jumps and layer thicknesses are then designed as matching layers. Alternatively, the coating 14 can also lie to the left of the film 151 in the composite, without limiting its functional capability.

The formation of an IR-reflecting coating, in particular a low-E coating based on silver layers is described in Hans-Joachim Glaser, “Dünnfilmtechnologie auf Flachglas [Thin Film Technogy on Flat Glass]”, pp. 167-171, the disclosure content of which is incorporated to the full extent in the present Application. While other metals such as gold or aluminum are also possible as IR-reflecting coatings, silver is preferred due to its good color effect (reflectance spectrum).

With use of the device particularly for display units outdoors, it is advantageous if, in order to increase the contrast during irradiation by direct sunlight, the outer side (OUTER), i.e., the side 111 of the device directed toward air is provided with a non-reflecting coating or an antireflection coating 161 and/or an anti-glare surface that diffuses light. In addition, as shown in FIG. 1b, the inner side (INNER), i.e., the side 121 of the device directed toward the back structure of the display unit, is provided with a non-reflecting coating or an antireflection coating 162. In a configuration with “optical bonding”, the back-side antireflection layer 162 is omitted, and side 121 is joined directly to the display by an adhesive with a matching refractive index. In this case, the back-side element 12 containing the filler material 153 can be omitted and is replaced by the frontmost panel of the adjacent display. In this case, the filler material 153 is the optical bonding layer and the element 162 is the front-side layer of a display. This front-side layer 162 then optionally contains, depending on the display technology, a polarization device in order to ensure the operation of the display.

In an enhanced embodiment, it is also possible that the antireflection layer 162 is omitted on the inner side and is replaced by an optically matched filler medium, which fills the intermediate space between the panel-shaped element 12 and the display device. In the enhanced embodiment, the second panel-shaped element 12 can also represent the front side of the display.

Antireflection coatings produced with the sol-gel method, sputtering or deposition methods are used, for example, as the non-reflecting coating or antireflection coating. Two exemplary embodiments shall be given below for such non-reflecting or antireflection coatings:

### EXAMPLE 1

Antireflection coating on one side, produced according to the sol-gel method:

The coating is composed of three individual layers in each case and has the structure: substrate+M+T+S. The individual layer characterized by T contains titanium dioxide TiO₂, the individual layer characterized by S contains silicon dioxide SiO₂, and the individual layer characterized by M is taken each time from S and T mixed solutions. The glass substrate is carefully cleaned prior to coating. The dip solutions are applied each time in rooms climatized to 28° C. with an air humidity of 5-10 g/m³ by means of the method of dip coating. The drawing rates for pulling the glasses out from the dip solution are approximately 275/330/288 mm/min for the individual layers M/T/S and depend on the concentration of solids in the solution, the solvent, generally ethanol, the temperature, and the viscosity of the solution. A process of heating in air follows the drawing of each gel layer. The heating temperatures and heating times amount to 180° C./2 min after the production of the first and second gel layers, and 440° C./60 min after the production of the third gel layer. In the case of the T layer, the dip solution (per liter) is composed of: 68 mL of titanium n-butylate, 918 mL of ethanol (abs), 5 mL of acetylacetone and 9 mL of ethyl butyl acetate. The dip solution for producing the S layer contains: 125 mL of silicic acid methyl ester, 400 mL of ethanol (abs), 75 mL of H₂O (dist.), 7.5 mL of acetic acid, and is diluted with 393 mL of ethanol (abs) after a standing time of approximately 12 hours. The coating solutions for producing the oxides with average refractive index are prepared by mixing of S+T solutions. The layer characterized by M is drawn from a dip solution having a silicon dioxide content of 5.5 g/L and a titanium dioxide content of 2.8 g/L. As a dip method, the applied wet-chemical, sol-gel process permits the economical coating of large surfaces, wherein two panels are adhesively bonded together prior to the dip process; thus, the necessary antireflection effect is achieved on one side. The adhesive is selected so that it is combusted at 440° C. within the above-described burning time, so that the panels exit the process separately.

### EXAMPLE 2

Antireflection coating on one side, produced according to the sputtering method: The coating is carried out in a continuous system with an MF sputtering process by magnetron sputtering, wherein the substrate is positioned on a so-called carrier and is transported on the latter through the sputtering production unit. Inside the coating production unit, the substrate is first pre-heated to approximately 150° C. for “dehydrating” the surfaces. Subsequently, an antireflection system (composed of four layers as an example) is produced as follows:
A) Sputtering of a high-refracting layer 1 at a feed of 1.7 m/min, wherein the carrier is suspended in front of the sputtering source and a layer of 30-nm thickness is deposited during this time. The layer is produced by introduction of argon and reactive gas under regulation of the reactive gas on a plasma impedance. The process pressure is determined, in particular, by the quantity of argon and oxygen that leads to typical process pressures in the range between 1*E-3 and 1*E-2 mbar. Deposition in plasma is performed via pulsing.
B) Sputtering of a low-refracting layer 2 with a feed of 2.14 m/min. A layer of 30.5 nm thickness is produced thereby. The layer is produced according to deposition underlayer 1.
C) Sputtering of a high-refracting layer corresponding to layer 1. Here, a layer of 54-nm thickness is produced at a feed of 0.9 m/min.
D) Sputtering of a low-refracting layer according to layer 2. At a feed of 0.63 m/min, a layer of 103-nm thickness is produced. Subsequently, the coated substrate along with the carrier is ejected via a transfer chamber.

With the non-reflecting or antireflection coatings, as described above, a contrast, which is defined as Tᵥᵢₛ/Rᵥᵢₛ, can be achieved in the range of 10 to 60, preferably 20 to 60, in particular 40 to 50 with standard light, whereas the contrast values are less than 7 for panels that are not non-reflecting. Rᵥᵢₛ designates the reflectance of a layer for standard light D65; Tᵥᵢₛ designates the transmittance, i.e., the reflectance and transmittance in the visible wavelength region from 350 to 780 nm.

In the example shown in FIGS. 1a-1b, the laminating films 151, 152, are designed in the same thickness of approximately 0.76 mm each, between which is found the film with the IR-reflecting coating, which is joined to the glass by the laminating films. In an alternative embodiment, however, these films can also be designed asymmetrically. Thus, the laminating film 151, through which sunlight passes prior to its reflection on the IR-reflecting layer 14, is configured thinner, having a thickness, for example, of 380 μm or 100 μm. In contrast, the laminating film 152 has a greater layer thickness, for example, of 700 μm. The thinner film thickness of the laminating film 151 has the advantage that less energy of the sunlight is absorbed and thus there results a smaller input of heat into the system or into device 1.

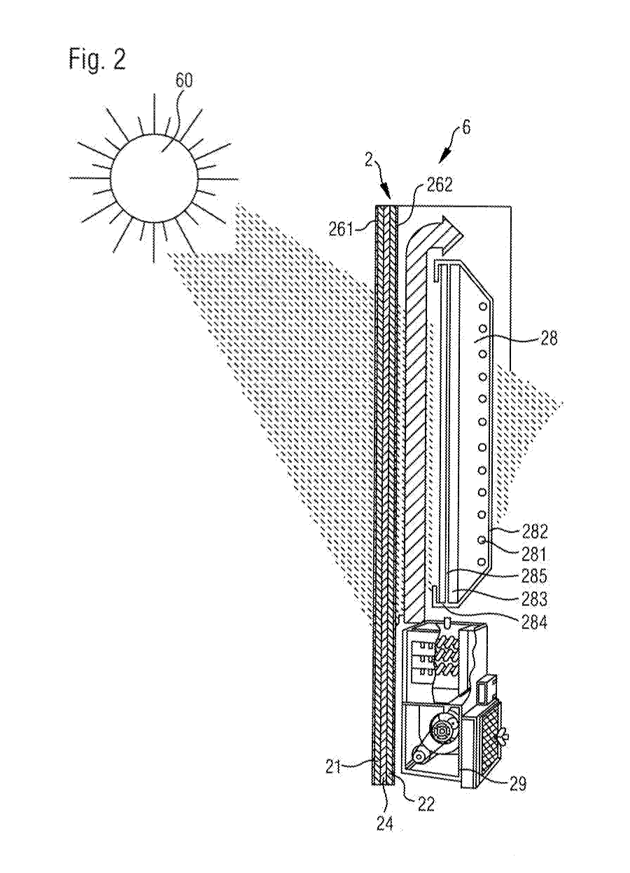

A display unit 6 having a device 2 according to the invention as a front panel for a display, here a liquid crystal display 28, is shown in FIG. 2. As was shown in FIGS. 1a-1b, the device 2 according to the invention is provided with a first panel-shaped element 21 and a second panel-shaped element 22, as well as an IR-reflecting layer 24 lying therebetween, and a non-reflecting or antireflection coating 261 applied onto the outer side of the first panel or of the first panel-shaped element 21 and a non-reflecting or antireflection coating 262 applied onto the outer side of the second panel or of the second panel-shaped element 22. The liquid crystal display 28 lying behind the device 2 formed as the front panel comprises a liquid crystal 283 having lighting means 281 introduced between two panels 284, 285, without limitation thereto. The entire liquid crystal display 28 is integrated into a housing 282. The liquid crystal display 28 is only one possible display; other possible displays comprise controllable LEDs or also OLEDs. Although a liquid crystal display is indicated, the invention is not limited thereto. The same components as in FIG. 1 are given similar reference numbers: the panel-shaped elements and the IR-reflecting layer have reference numbers increased by 10; the non-reflecting and antireflection layers have reference numbers increased by 200. The laminating films from FIG. 1 are not explicitly shown for the device in FIG. 2, but the device is usually constructed the same as the device 1 in in FIG. 1, although generally not shown to be present.

The device 2 according to the invention, as a front panel, extensively prevents light of sun 60 from heating the intermediate space between the front panel of 2 and the liquid crystal display 28. Nevertheless, however, it is necessary, based on the intrinsic evolution of heat of the liquid crystal display 28, each time depending on the design of the display unit, to actively cool the latter, as shown here, for example with a cooling device 29. The cooling device 29, however, can be dimensioned essentially smaller than in the prior art, since a smaller input of heat based on solar irradiation occurs between the panel and the liquid crystal display.

For the optical contrast of the entire display device, it is important to take care that the display itself does not engender too much reflection, since if it did, the advantage of the antireflection effect of the front panel described in the invention would not be fully brought to bear.

In the case of other units, in particular smaller display units, in an alternative embodiment of the invention, the device 2 can also be bonded or laminated directly as the front panel onto the panel 284 of the display unit. This is designated “optical bonding”. The device 2 can also be utilized directly as the front panel instead of panel 284 as the delimitation to the liquid crystal 283, which offers an advantage relative to structural size and weight.

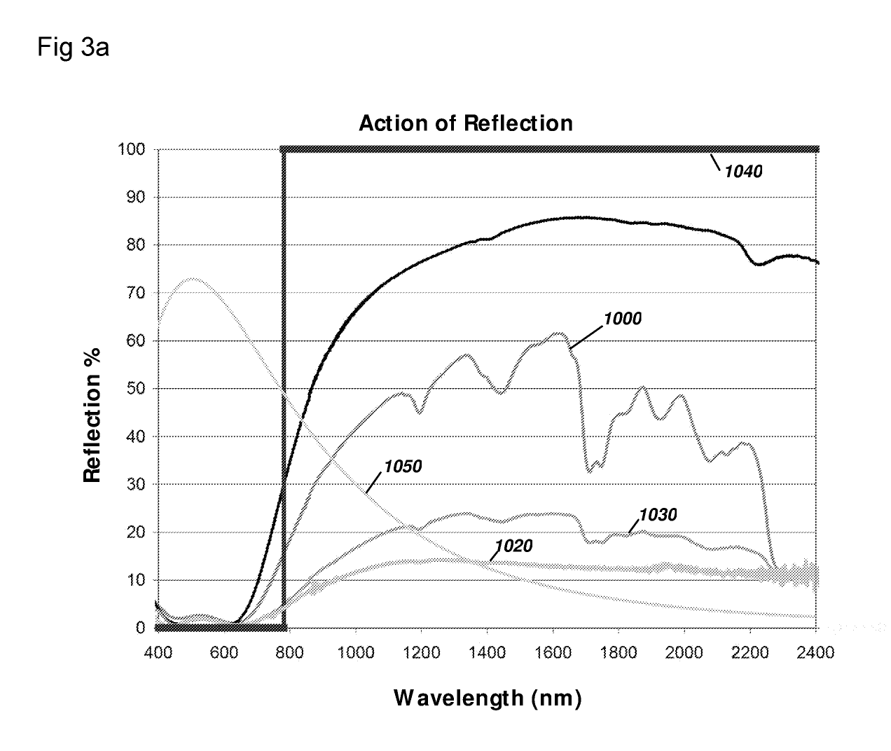

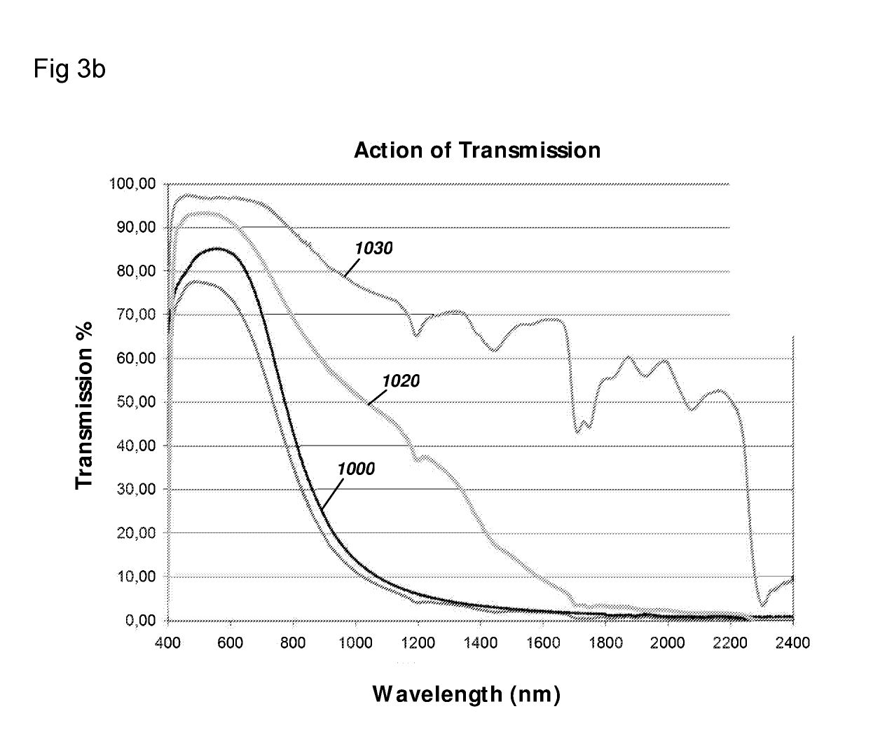

FIG. 3a shows the reflectance for devices having different layer systems over a wavelength range from 300 nm to 2500 nm.

The associated transmission values for the same layer systems having the same numbering are shown in FIG. 3b.

Designated here is reference number 1000 for a system made of a silver-based coating as the IR-reflecting layer, based on the product XIR70 of the Southwall company; reference number 1020 for an IR-reflecting film Siplex Solar Control having a non-reflecting layer; as well as reference number 1030 for an antireflection coating without IR-reflecting coating (CONTURAN of the SCHOTT company) for comparison. Additionally shown in FIG. 3a is the curve of an ideally reflecting IR mirror 1040, which reflects all wavelengths above 780 nm, the limit of visible light, and the idealized intensity distribution of the solar spectrum 1050, which is approximated as a Planck radiator having a surface temperature of 5762 K. Here, absorption bands were ignored in the spectrum for purposes of simplification. All devices involve a composite system with first and second panel-shaped elements and the corresponding coatings. The data given in Table 1 for the reflectance Rᵥᵢₛ and transmittance Tᵥᵢₛ in the visible wavelength region as well as the IR transmittance T(IR) and the IR solar reflectance refer to the total system, i.e., the laminated glass element composed of two panel-shaped elements with the corresponding coatings. In each case, these systems contain two antireflection layers 161, 162 according to FIG. 1, but have different IR-reflection layers. In this respect, refer to FIG. 1b.

The data for the different layer systems that are shown in FIGS. 3a and 3b are given in Table 1.

| System (panel 1/IR | | | T (IR) | IR solar |
|---|---|---|---|---|
| layer/panel 2) | Rᵥᵢₛ (D65) | Tᵥᵢₛ (D65) | 780-2000 nm | reflection |
| CONTURAN | 1% | 96% | 67% | 17% |
| antireflection | | | | |
| coating (1030) | | | | |
| IR-reflecting film | 1.5% | 92% | 28% | 11% |
| Siplex Solar + | | | | |
| antireflection coating | | | | |
| (1020) | | | | |
| Silver-based IR- | 1.6% | 79% | 3.5% | 68% |
| reflection layer | | | | |
| Southwall XIR70 | | | | |
| film + antireflection | | | | |
| layer (1000) | | | | |

As found from Table 1, the highest contrast, namely Tᵥᵢₛ/Rᵥᵢₛ=50, with the highest transmittance Tvis, namely 79%, with the highest IR solar reflection of 68% and lower IR transmittance T(IR) of only 3.5% occurs for the device according to the invention made of two panels with a silver-based IR reflection system lying therebetween in combination with an antireflection coating on the first and/or the second panel(s) of the laminate system.

By means of an approximated solar spectrum, which can be well represented by a Planck radiator with T=5762 K, one can derive how much energy of sunlight is eliminated in the IR region above 780 nm to 2500 nm: thus, approximately 45% of the solar energy lies in this region and approximately 55% lies in the region of 350 nm-780 nm. Here, UV components below 350 nm were disregarded, since the transmission here is already clearly reduced by the solid or liquid filler material. Wavelengths above 2500 nm were also not considered, since glass itself strongly absorbs above 2500 nm.

In addition to the approximated solar spectrum 1050, an ideal IR mirror 1040 that has no reflection in the visible region below 780 nm and shows 100% reflectance above 780 nm is also shown in FIG. 3a. This ideal design of the mirror makes possible a reflection of approximately 45% of the relevant solar radiation without adversely affecting the visible region. The numerical values of IR reflection are given relative to this ideal IR mirror in this Application.

If one combines the spectral reflectances of the examples from FIG. 3a with the relative intensity of the approximated solar spectrum, which is approximated as the Planck radiator with T=5762 K, then one can determine how much radiation from the sun is reflected in the IR region above 780 nm. This value, referred to the reflectance of the idealized IR mirror having 100% reflection above 780 nm, is defined as IR solar reflectance in this Application.

It can be seen from Table 1 that 30% of the energy of the total solar spectrum can be reflected by means of the silver-based reflection layer described here, which corresponds to an IR solar reflectance of 68% when compared with the ideal mirror with the curve 1040, whereas, with a SIPLEX film, which corresponds to curve 1020, only 5% is possible, which corresponds to an IR solar reflectance of 11% when compared to the ideal mirror.

It is clear to a person skilled in the art that in practical embodiments, portions of the visible spectrum of curves 1000, 1100, 1040 and 1050 can still be utilized for IR reflection, since the eye always acts insensitively at the edges of the visible region. Simplicity was introduced by means of the ideal mirror for determining the effectiveness.

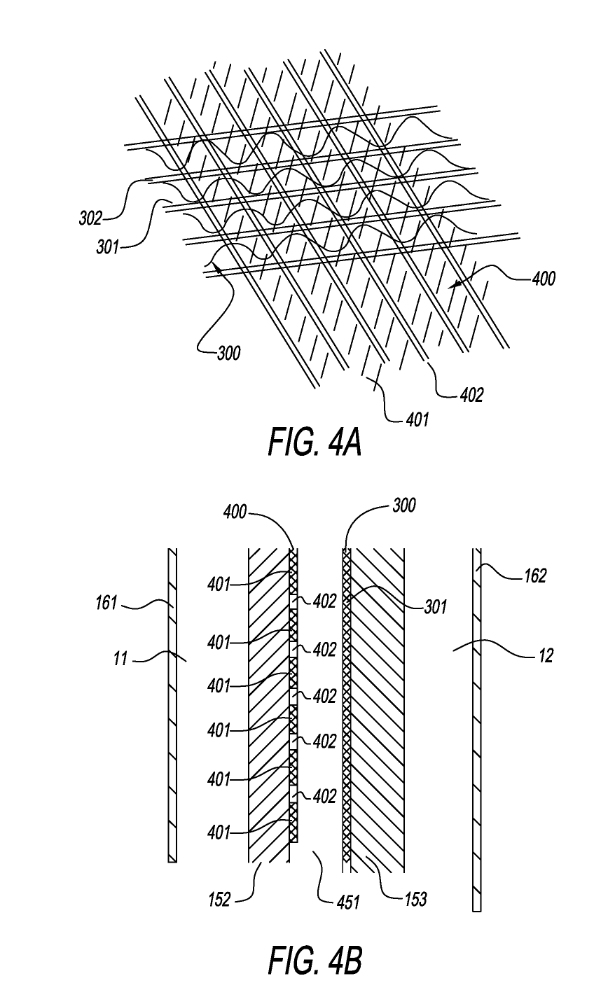

FIGS. 4a to 4b show the structure in principle of a device having an IR-reflecting coating according to the invention in the embodiment as a projected-capacitive touch screen. The special feature of the embodiment shown in FIGS. 4a-4b is that the conductive layers are also simultaneously the IR-reflecting layers.

FIGS. 4a and 4b show the simplified structure of a device for detection of a touch signal. In this case, two conductive, structured layers 400 and 300 are separated from one another by an insulating intermediate layer 451, so that it is possible to determine the position of the signal on the surface by the structuring of layers 400 and 300, which are placed orthogonal to one another. In a preferred embodiment, the insulating layer 451 is composed of the same material as the insulating layer 151 of the structure according to FIGS. 1-3. The structuring of the layer 300 is carried out so that the conductive track 301 in the x-direction is separated from the neighboring conductive track by a non-conductive discontinuity 302. Such discontinuities can be carried out, for example, by the lithographic etching method or laser structuring. Analogous to this is the structure in the y-direction, in which the conductive tracks 401 are separated by non-conductive regions 402. The two structured conductive regions 300 and 400 are electronically separated, whereby the change in capacity that a capacitor formed from the conductive layers 301 and 401 has with an insulating layer is measured. The drawings of FIGS. 4a and 4b are very greatly simplified. The insulation material or the insulating layer 451 is not necessarily a polymer film, as shown, e.g., in FIG. 1b. The insulation material 451 can also be a glass. As previously described, the insulation material 451 bears the IR-reflecting coating. The conductive layers 400, 300 present in FIG. 4b are simultaneously the IR-reflecting layers. The panels 11, 12, which enclose the insulation material, are disposed above and below the laminating films 152, 153.

FIG. 4b shows the same structure as FIG. 4a, but as a cross section. This will clarify that a non-conductive layer 451, which can be formed as a film, lies between the structured layers 400 and 300 with conductive tracks 301, 401. The discontinuities of layers 400 and 300 shown in FIG. 4a are shown as discontinuities in the conductive track 401 in FIG. 4a, whereby, in this section, the direction was selected such that conductive track 301 is continuous and conductive track 401 comprises non-conductive discontinuities 402. Of course, this can vary depending on the sectioning angle.

The person skilled in the art is familiar with how such structures are introduced. As described above, the conductive layers 400, 300 form the IR-reflecting coating on the insulation material 451 itself. The IR-reflecting layers comprise silver, for example, and are conductive for this reason. Due to the very thin silver layers of less than 10 nm, the silver layers have a high optical transmission. This can be seen from the optical data in Table 1. Thus, absorption in the silver layers is responsible for the fact that, in the example of embodiment, only a transmission of 79% is obtained in the “silver-based IR-reflection layer”, in contrast to the example of embodiment with the non-absorbing CONTURAN layer (transmission: 96%). Despite the low transmission in the case of the silver-based IR-reflection layers in the visible wavelength region (VIS light), enough optical radiation is still transmitted, so that one can still see through the entire element. Since two conductive layers 400, 300 are provided, the embodiment in FIG. 4b also comprises two IR-reflecting coatings on the insulation material 451. In the sense of the invention, it is advantageous that the non-conductive regions of layers 402 and 302 are smaller in terms of area than the conductive regions 401 and 301, since, due to the formation of the conductive layers 300, 400 as IR-reflecting layers, the IR radiation can fall on the display in the regions 302 and 402. Due to the orthogonally disposed discontinuities 302 and 402, however, only the points of intersection are free of the conductive coating and thus the IR-reflecting coating, and therefore are small in terms of area. In the embodiment shown, whereas the IR-reflecting and conductive layers are disposed on opposite-lying sides of the insulation material 451, it is also possible in an alternative embodiment of the invention that the two layers 300 and 400 that are disposed orthogonal to one another can also be disposed on the same side of the insulation material 451. In such a case, however, another insulation material must be introduced between these two layers in order to prevent conductivity between layers 300 and 400.

The thickness of the silver layers that have a silver fraction that is as high as possible and are used as the IR-reflecting coating and the conductive coating, preferably amounts to less than 20 nm. The lower limit for such layers is a thickness of 1 nm. The preferred region for the thickness of the conductive and IR-reflecting layers containing silver thus lies between 1 nm and 20 nm, preferably between 1 nm and 10 nm.

Due to the system according to the invention of a composite panel with IR-reflecting coating, as described above, it is possible, for the first time, to combine a high optical contrast in the visible wavelength region, in particular for an outdoor application in the field of displays, with a high IR reflectance, and thus to reduce the input of heat due to near-IR solar radiation. Another advantage is the simple manufacture, since standard coating processes for silver-based, low-E coatings can be employed for the production of the IR coating.

It is understood that the invention is not limited to one combination of the above-described features, but rather that the person skilled in the art will combine all features of the invention as he wishes, as long as this is meaningful, or will use any one of these alone, without departing from the scope of the invention. Other embodiments are possible.

1-15. (canceled)

16. An indicator or display unit device, comprising:
a first panel element;
a second panel element;
an IR-reflecting coating between the first and second panel elements;
a filler material between the first and second panel elements, wherein the first panel element, the second panel element, the IR-reflecting coating, and the filler material form a composite;
an antireflection coating in the visible wavelength region is on an outer side of the first panel element and/or on an outer side of the second panel, wherein the filler material comprises a first laminating film, a second laminating film, and an additional film between the first and the second laminating films, the IR-reflecting coating being on the additional film;
an IR solar reflectance that lies in a range of 45% to 95% in a wavelength region of 780 nm to 3000 nm; and
a reflectance Rᵥᵢₛ that is less than or equal to 4% in the visible wavelength region of 400 nm to 780 nm.

17. The device according to claim 16, wherein the additional film comprises is an organic or an inorganic film with a thickness between 10 μm and 5 mm.

18. The device according to claim 16, wherein the IR solar reflectance lies in a range of 50% to 90%.

19. The device according to claim 16, wherein the reflectance Rᵥᵢₛ is less than or equal to 3%.

20. The device according to claim 16, wherein the reflectance Rᵥᵢₛ is less than 2%.

21. The device according to claim 16, wherein the first and/or second panel element has an edge that does not have the IR-reflecting coating.

22. The device according to claim 21, wherein the edge has a sealing material.

23. The device according to claim 16, wherein the IR-reflecting coating is a coating selected from the group consisting of a low-E coating, a solar-protection coating, a coating of a highly conductive metal layer, and a coating of at least two metal layers separated by an oxide layer.

24. The device according to claim 16, wherein the antireflection coating comprises a structure that is applied with a method selected from the group consisting of a sol-gel technique as a single interference coating, a sol-gel technique as a multiple interference coating; and a sol-gel technique as a triple interference coating with a first layer having a refractive index between 1.6 and 1.8, a second layer having a refractive index between 1.9 and 2.5, and a third layer having a refractive index between 1.4 and 1.5; a high-vacuum technique as a single layer system; a high-vacuum technique as a multiple interference layer system; a sputtering process; a deposition process; an online CVD process; an offline CVD process; an etching process as a porous layer; and an etching process as a light-scattering surface.

25. The device according to claim 16, further comprising an optically matching filler medium filling an intermediate space.

26. The device according to claim 16, wherein the second panel element represents a front side of the device.

27. The device according to claim 16, wherein the IR-reflecting coating is simultaneously an electrically conductive layer that is structured with a discontinuous conductivity in the layer plane and conductive tracks that are configured for a use as an electrode structure.

28. A display unit comprising:
a liquid crystal display unit,
a plasma display unit,
an LED or an organic LED display unit, and
a front panel comprising the device according to claim 1.

29. A touch screen, comprising the device according to claim 1.

30. The touch screen according to claim 14, wherein the IR-reflecting coating is optically matched so that a conductive track structure of the touch screen is not visible.
